(19) United States
(12) Patent Application Publication
(10) Pub. No.: US 2006/0132241 A1
(43) Pub. Date: Jun. 22, 2006

(54) Transistor integrated circuit device and manufacturing method thereof

(76) Inventors: Katsuhiko Kawashima, Hyogo (JP); Masahiro Maeda, Osaka (JP); Keiichi Murayama, Toyama (JP); Hirotaka Miyamoto, Osaka (JP)

Correspondence Address: PANASONIC PATENT CENTER;c/o MCDERMOTT WILL & EMERY LLP, 600 13TH STREET, NW, WASHINGTON, DC, 20005-3096, US

(21) Appl. No.: 10/545,786

(22) PCT Filed: Oct. 8, 2004
(86) PCT No.: PCT/JP04/15327

§ 371 Date: Aug. 16, 2005

(30) Foreign Application Priority Data
Oct. 14, 2003 (JP) 2003-354095

(51) Int. Cl. H03F 3/191

(52) U.S. Cl. 330/302

(57) ABSTRACT

There are provided a transistor integrated circuit device which reduces the integrated area of a circuit while avoiding an element destruction caused by thermal runaway, and a method of manufacturing the transistor integrated circuit device. A cut capacitor (13) is composed of an upper electrode formed from a wiring metal and in a first layer; and a lower electrode formed from a wiring metal and in a second layer. A bias resistor (12) is formed from the same wiring metal as that of the lower electrode of the cut capacitor (13). This bias resistor (12) is formed from a wiring metal which is made into a thin film to function as a sheet resistor, and the resistance value of the bias resistor (12) can be freely set according to the thickness or width of the wiring metal.

### TECHNICAL FIELD

The present invention relates to a transistor integrated circuit device and a method of manufacturing the transistor integrated circuit device, and more particularly to a device (a semiconductor chip, etc.) in which circuits each composed of a transistor, a resistor, a capacitor, etc., are integrated on a semiconductor substrate, and a method of manufacturing such an integrated circuit.

### BACKGROUND ART

As is commonly known, a circuit of a power transistor which handles high-frequency signals uses a configuration in which a plurality of transistors (e.g., heterojunction bipolar transistors) are connected in parallel, in order to ensure high-frequency characteristics (FIG. 8). In FIG. 8, a direct-current voltage (a bias voltage) is applied through a common bias resistor 102 to a base of each transistor 101, and also a high-frequency signal is inputted through a common cut capacitor 103 to the base of each transistor 101. An emitter of each transistor 101 is grounded, and output signals from the transistors 101 are outputted from their respective collectors which are commonly connected to one another.

The circuit shown in FIG. 8 is an ideal circuit for the case where it is assumed that the operations of elements are uniform without variation. In reality, however, since there is variation in characteristics, etc., between the elements, the operations of the elements are not uniform. Therefore, in this circuit, there remains a problem that a transistor(s) may go into thermal runaway due to an increased calorific value during operation, and the base current of the transistor(s) may increase, which may possibly cause the phenomenon of element destruction.

In order to solve such a problem, a technique may be considered which prevents an increase in base current by inserting a protection resistor 104 to the base of each transistor 101 (FIG. 9). This technique, however, causes a reduction in circuit gain because of the protective resistors 104, and thus is not suitable for a power transistor circuit. In this view, a technique of configuring a transistor circuit in a cell form is proposed in U.S. Pat. No. 5,608,353 (patent document 1), U.S. Pat. No. 5,629,648 (patent document 2), Japanese Laid-Open Patent Publication No. 2001-196865 (patent document 3), and the like. A circuit disclosed in these patent documents is configured such that a transistor circuit (dotted-line portion) composed of a transistor 101, a bias resistor 102, and a cut capacitor 103 is configured in a cell form and the cells are connected in parallel (FIG. 10). By the configuration in which each transistor 101 is provided with the bias resistor 102 and the cut capacitor 103, the circuit of these patent documents prevents an increase in base current caused when thermal runaway occurs.

In the case where the transistor circuits in a cell form of the aforementioned patent documents 1 to 3 are integrated on a semiconductor substrate, an element arrangement such as, for example, the one shown in a bird's-eye view and a side view of FIG. 11 may be considered. In FIG. 11, a cut capacitor 103 is composed of an upper electrode formed from a wiring metal (Au) and in a first layer; and a lower electrode formed from a wiring metal (Au) and in a second layer. A bias resistor 102 is formed from a resistor metal (NiCr, TaN, etc.) having a sheet resistance of the order of 50 Ω to 100 Ω. This resistor metal, however, is susceptible to stress, and thus cannot be multilayered with a wiring metal, etc. For this reason, a conventional manufacturing technique of an integrated circuit requires an exclusive space for the bias resistor 102, as is shown in FIG. 11, which causes the problem of an increase in integrated area per cell. This problem becomes more prominent in circuit, such as of power transistors, in which a number of cells need to be connected in parallel (FIG. 12).

### DISCLOSURE OF THE INVENTION

Therefore, an object of the present invention is to provide a transistor integrated circuit device which realizes, with the use of a characteristic manufacturing technique of a resistor, a reduction in the integrated area of the circuit while avoiding an element destruction caused by thermal runaway, and a method of manufacturing the transistor integrated circuit device.

In order to achieve the above object, the transistor integrated circuit device of the present invention in which a circuit is integrated on a semiconductor substrate has the following features.

A feature of the present invention is that, among circuits integrated on a semiconductor substrate, in particular for a circuit which includes at least one transistor; a capacitor having electrodes, to one of which a signal is inputted, and an other of which is connected to a base terminal of the at least one transistor; and a resistor having terminals, to one of which a direct-current voltage is applied, and an other of which is connected to the base terminal of the at least one transistor, normally, the resistor is formed from a wiring metal used to connect between elements of multiple layers, which is made into a thin film, rather than a resistor metal (NiCr, TaN, etc.) having a sheet resistance of the order of 50 Ω to 100 Ω.

In this case, it is preferable that the resistor be formed integrally with the other electrode of the capacitor, using a same wiring metal as that of the other electrode of the capacitor. Alternatively, it is preferable that the resistor be formed so as to be multilayered with a wiring for supplying the direct-current voltage. Further, the circuit may include one resistor and one capacitor per two to five transistors. Here, the definition of one transistor is clarified. The high frequency performance of a bipolar transistor improves as the capacity between a base and a collector decreases. Hence, generally, by reducing a base region sandwiched between collector regions as much as possible, the capacity between the base and the collector is reduced. Thus, in power transistors, unit cells each provided such that the above base region with a small area is sandwiched between the collector regions, are connected in parallel to synthesize outputs of the cells. Accordingly, in the case where one base region is sandwiched between two collector electrodes, such a region is counted as one transistor.

The transistor integrated circuit device having the aforementioned features is realized by a method of manufacturing an integrated circuit, in which the resistor is formed using a wiring metal which is made into a thin film; a method of manufacturing an integrated circuit, in which the resistor is formed integrally with the other electrode of the capacitor, using a same wiring metal as that of the other electrode of the capacitor and in a same manufacturing step as that for the other electrode of the capacitor; and a method of manufacturing an integrated circuit, in which the resistor is formed so as to be multilayered with a wiring for supplying the direct-current voltage.

As mentioned above, according to the present invention, since a wiring metal made into a thin film is used as a resistor, an element destruction caused by thermal runaway can be avoided, and also the integrated area of a circuit can be reduced. In addition, by adopting a circuit in which one resistor and one capacitor are arranged per two to five transistors, the integrated area of the circuit can be further reduced, and stabilization of circuit characteristics and an improvement in heat radiation characteristics can be expected as well. Furthermore, according to the method of manufacturing a transistor integrated circuit device, the number of manufacturing steps can be reduced relative to the conventional method.

### BRIEF DESCRIPTION OF THE DRAWINGS

FIG. 1 is a diagram illustrating an exemplary transistor circuit composed of a transistor, a bias resistor, and a cut capacitor.

FIG. 2 is a diagram illustrating a transistor integrated circuit device according to one embodiment of the present invention in which the transistor circuit of FIG. 1 is integrated.

FIG. 3 is a diagram for describing that an integrated area is reduced by the transistor integrated circuit device according to the embodiment of the present invention.

FIG. 4 is a diagram showing the relationship between the number of transistors per cell and a destructive VSWR.

FIG. 5 is another diagram for describing that the integrated area is reduced by a transistor integrated circuit device according to one embodiment of the present invention.

FIG. 6 is a diagram for describing a method of manufacturing a transistor integrated circuit, according to one embodiment of the present invention.

FIG. 7 is a diagram for describing a conventional method of manufacturing a transistor integrated circuit.

FIG. 8 is a diagram illustrating exemplary conventional power transistor circuit which handles high frequency signals.

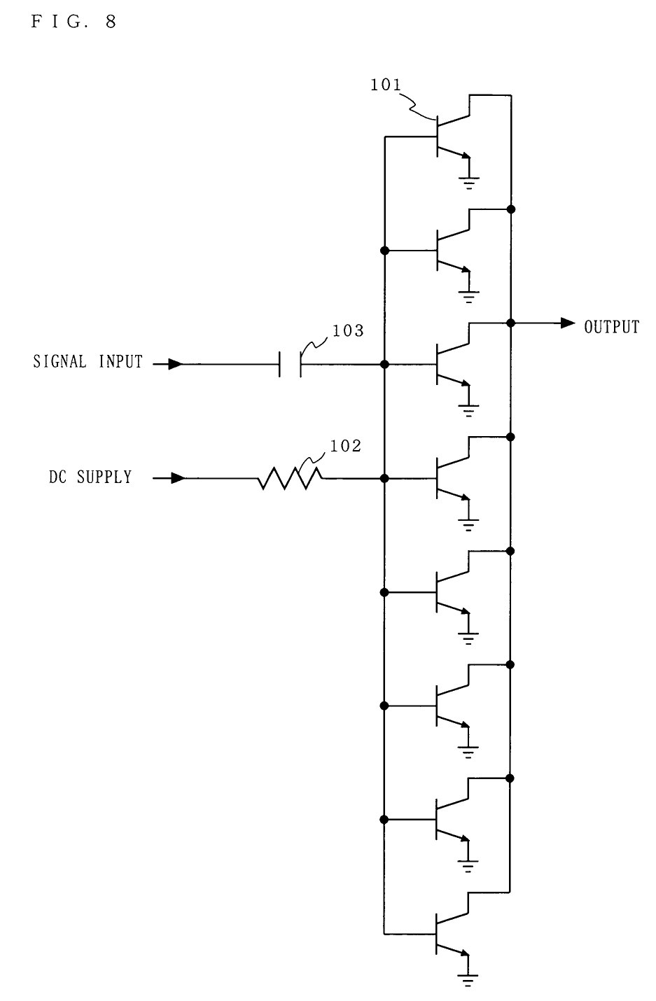

FIG. 9 is a diagram illustrating another exemplary conventional power transistor circuit which handles high frequency signals.

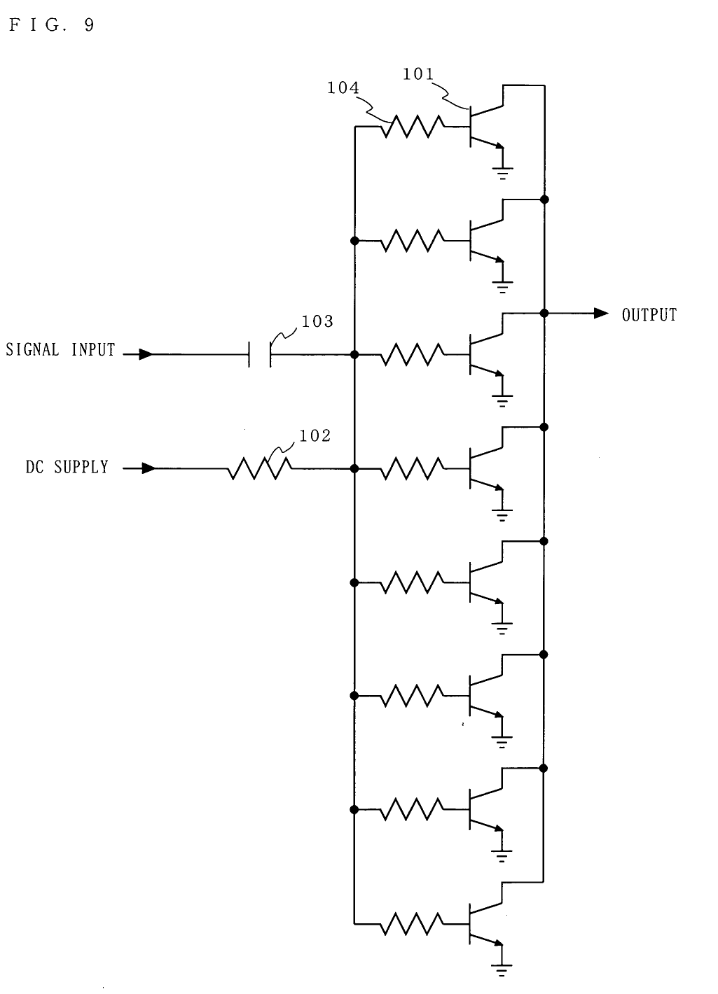

FIG. 10 is a diagram illustrating still another exemplary conventional power transistor circuit which handles high frequency signals.

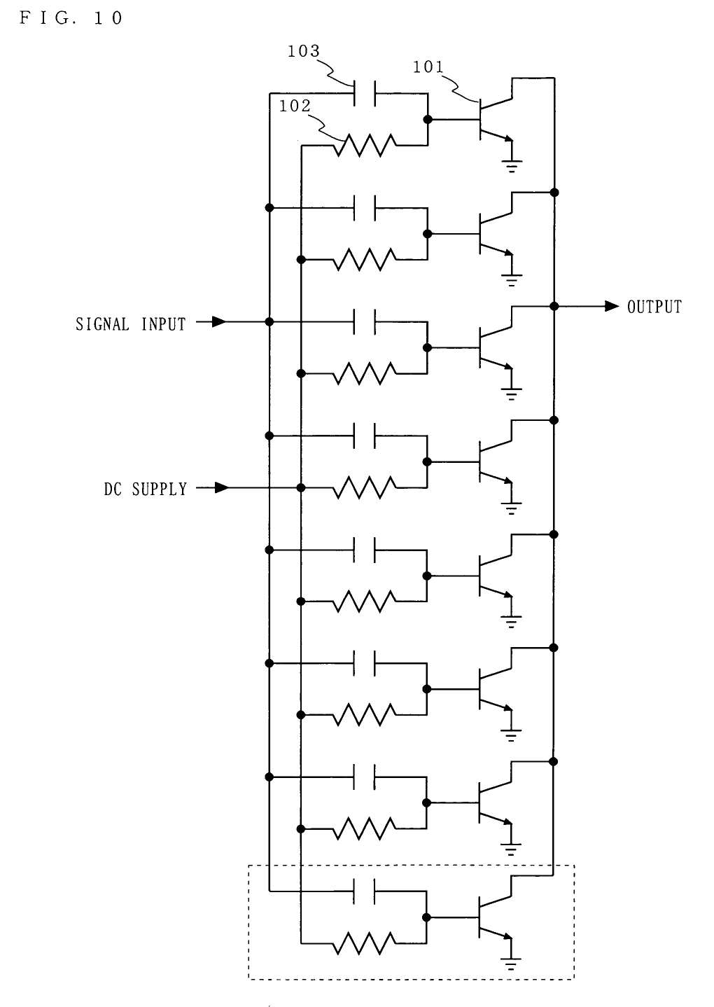

FIG. 11 is a diagram illustrating a semiconductor substrate having a transistor circuit in FIG. 10 integrated thereon.

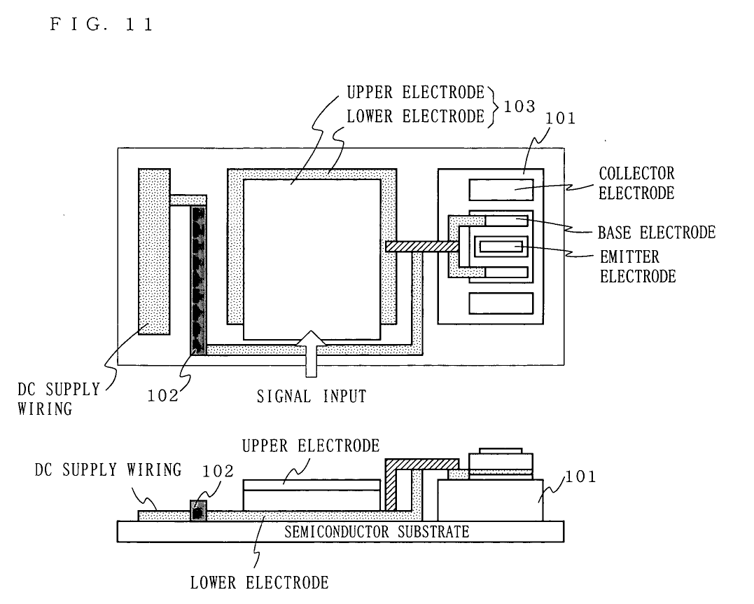

FIG. 12 is a diagram illustrating exemplary power transistor circuit in which a plurality of integrated circuits of FIG. 11 are connected in parallel.

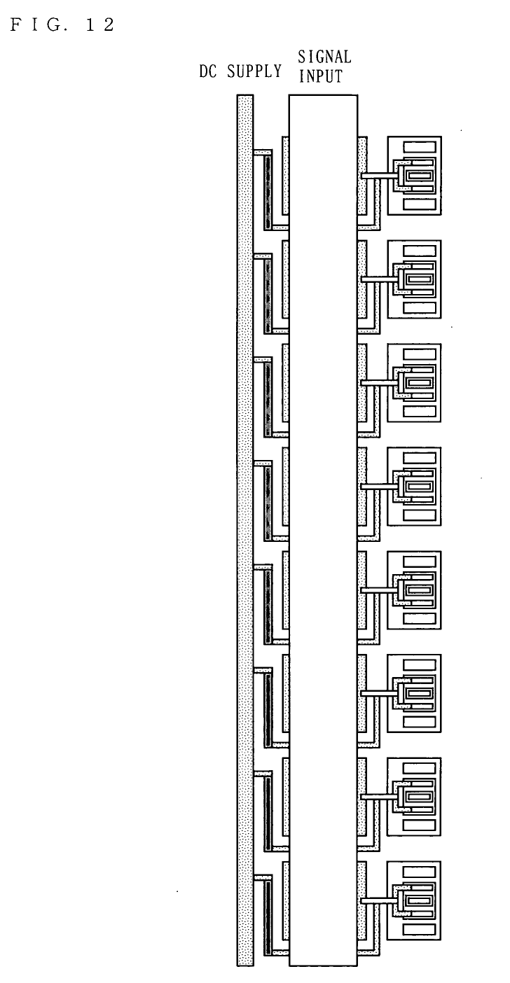

### BEST MODE FOR CARRYING OUT THE INVENTION

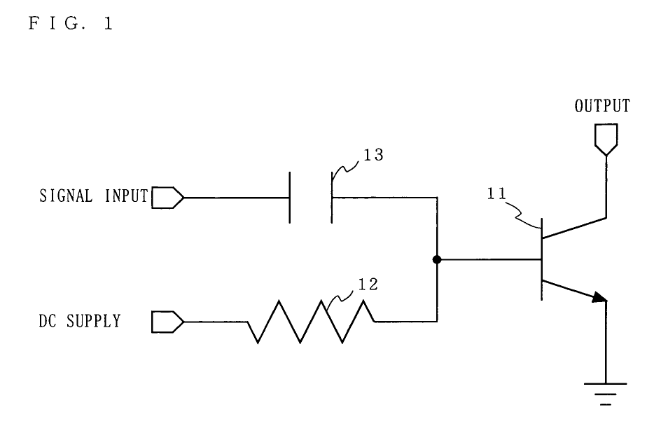

A best mode embodiment of the present invention will be described by showing an example where a transistor circuit (FIG. 1) composed of a transistor 11, a bias resistor 12, and a cut capacitor 13, as described in the foregoing background art, is integrated on a semiconductor substrate.

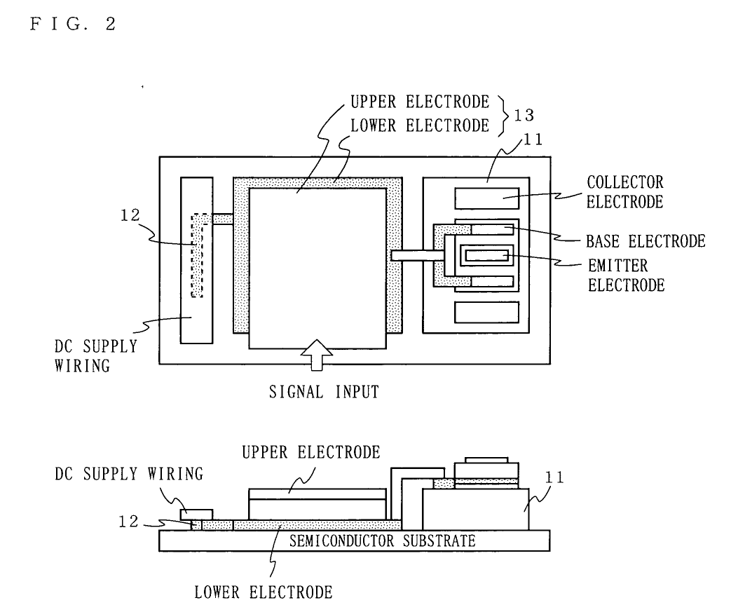

FIG. 2 is a bird's-eye view and a side view of a transistor integrated circuit device according to one embodiment of the present invention in which the transistor circuit of FIG. 1 is integrated. In FIG. 2, a cut capacitor 13 is composed of an upper electrode formed from a wiring metal (Au) and in a first layer; and a lower electrode formed from a wiring metal (Au) and in a second layer. A bias resistor 12 is formed from the same wiring metal as that of the lower electrode of the cut capacitor 13. This bias resistor 12 is formed from a wiring metal which is made into a thin film to function as a sheet resistor, and the resistance value of the bias resistor 12 can be freely set according to the thickness or width of the wiring metal. Note that though in an example shown in FIG. 2, the bias resistor 12 is formed at the lower electrode layer of the cut capacitor 13, the bias resistor 12 may be formed at the upper electrode layer using the same wiring metal.

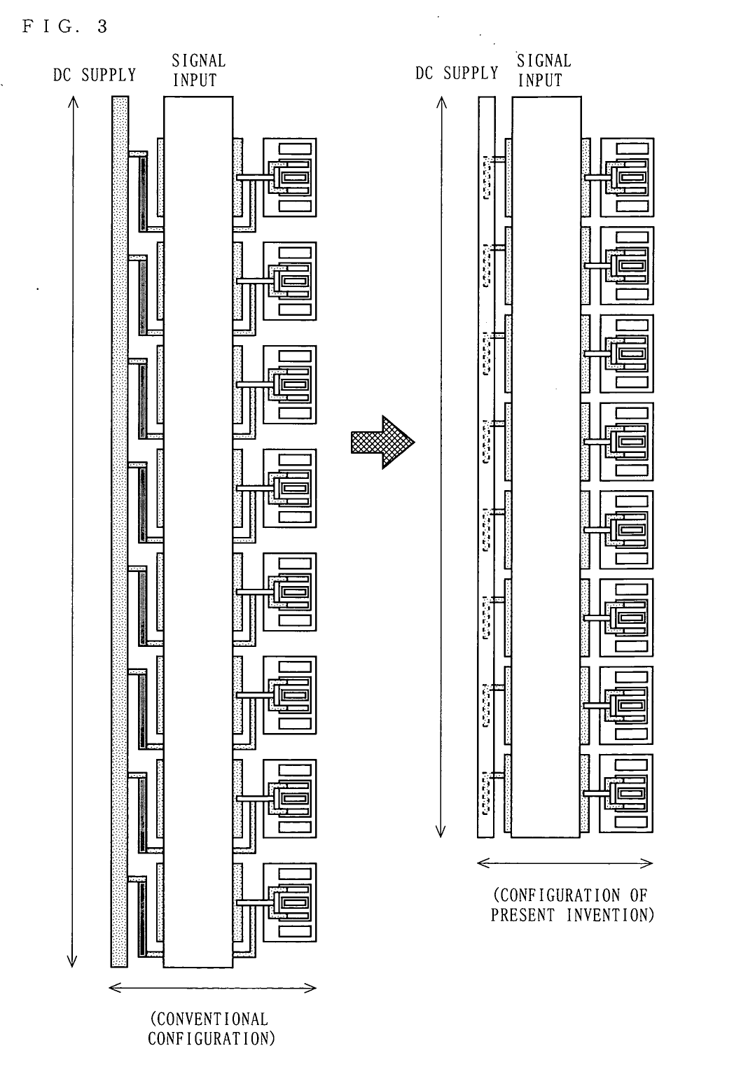

The present invention is characterized in that the bias resistor 12 is formed from a wiring metal which is made into a thin film, as is described above. By this characteristic, unlike the conventional resistor metal (NiCr, TaN, etc.), the need to consider stress to the bias resistor is eliminated, making it possible to obtain a structure in which a wiring metal, such as a wiring for supplying a DC, and the bias resistor 12 are multilayered (FIG. 2). By this structure, an exclusive space for the bias resistor is no longer required, whereby an advantageous effect of reducing an integrated area per cell is produced. This advantageous effect becomes more prominent in a circuit, such as of a power transistor, in which a number of cells need to be connected in parallel (FIG. 3). As can be seen in FIG. 3, according to the present invention, since both the vertical and horizontal dimensions are reduced relative to a conventional integrated area, the circuit can be composed with a smaller integrated area.

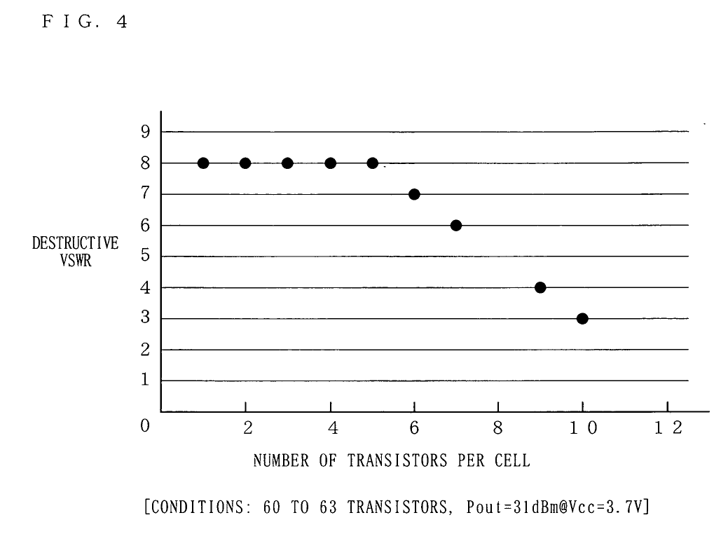

As described in the foregoing background art, as for a measure against a thermal runaway phenomenon caused by variation in characteristics between the elements, or the like, a configuration in which each transistor 11 is provided with a bias resistor 12 and a cut capacitor 13 is most preferable. However, as shown in FIG. 4, the inventors have verified by an experiment that the resistance to an element destruction caused by thermal runaway does not change if the number of transistors 11 included in a single cell is up to five.

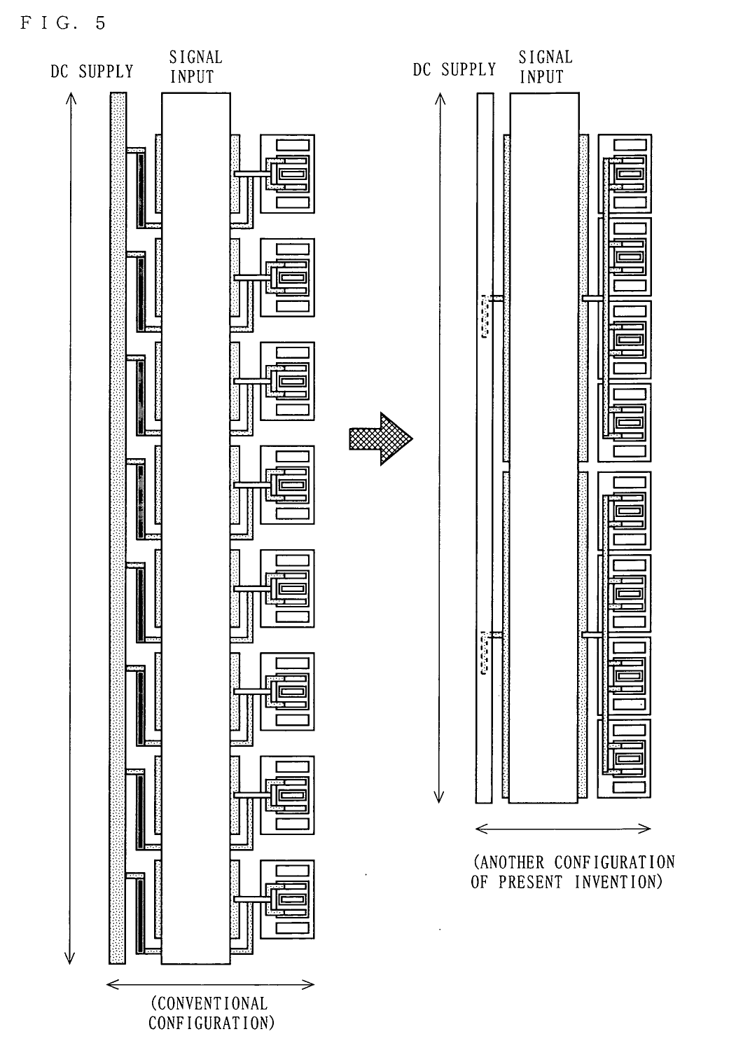

Accordingly, it is also possible to adopt a cell structure, using the technique of forming the bias resistor 12 of the present invention, in which one bias resistor 12 and one cut capacitor 13 are provided per a plurality of transistors 11 (four in an example of FIG. 5). This cell structure further reduces the vertical dimension, and thus the circuit can be composed with an even smaller integrated area. Also, since this cell structure can reduce the number of the cut capacitors 13 and the number of the bias resistors 12 formed on the semiconductor substrate, variation between the elements is reduced, and accordingly, stable circuit characteristics can be obtained.

In addition, in the case where only one common bias resistor 12 is provided for n transistors 11, the value of the bias resistor 12 is reduced to one n-th of that for the case where n bias resistors 12 in total are provided to the n transistors 11, respectively. To put it the other way around, by forming only one bias resistor 12, a bias resistance value of n times is applied to each of n transistors 11. Thus, there is an advantage that even if the sheet resistance value of a wiring metal which forms the bias resistor 12 is as small as several Ωs or less, a required bias resistance value can be easily achieved without increasing the ratio of length to width of the wiring metal.

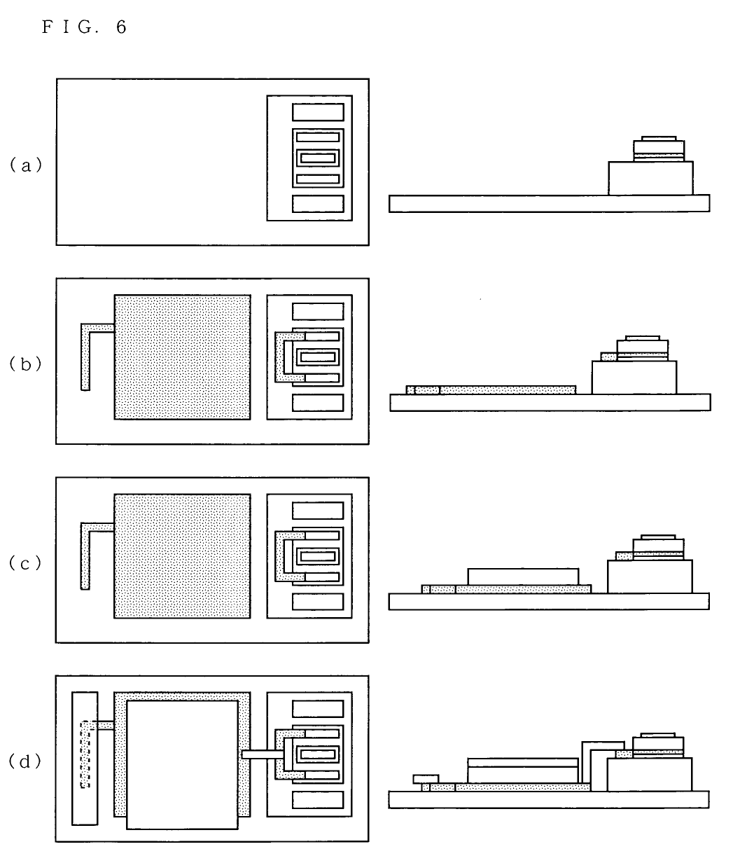

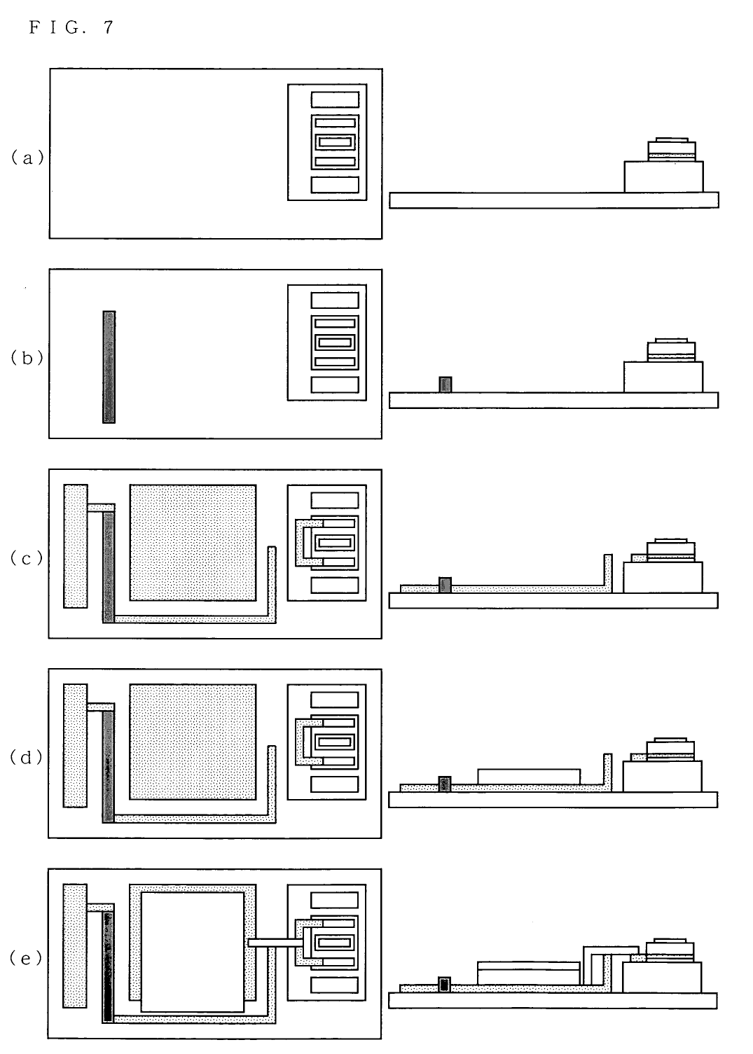

Next, it is described that a transistor circuit having the above-described structure can not only reduce the integrated area but also simplify the manufacturing process. FIG. 6 is a bird's-eye view and a side view for describing a method of manufacturing a transistor integrated circuit, according to one embodiment of the present invention. FIG. 7 is a bird's-eye view and a side view for describing a conventional method of manufacturing a transistor integrated circuit.

First, in both a manufacturing process of the present invention and a conventional manufacturing process, a transistor is formed ((a) in FIG. 6 and (a) in FIG. 7). Next, in the conventional manufacturing process, a resistor is formed from a resistor metal ((b) in FIG. 7). Next, in both the manufacturing process of the present invention and the conventional manufacturing process, a lower electrode of a capacitor and a first-layer wiring are formed ((b) in FIG. 6 and (c) in FIG. 7). In the present invention, in this manufacturing step, a resistor is formed at the same time. Next, in both the manufacturing process of the present invention and the conventional manufacturing process, a dielectric for the capacitor is formed ((c) in FIG. 6 and (d) in FIG. 7). Finally, in both the manufacturing process of the present invention and the conventional manufacturing process, an upper electrode of the capacitor and a second-layer wiring are formed ((d) in FIG. 6 and (e) in FIG. 7). As can be seen, the manufacturing process of the present invention has one step less than the conventional manufacturing process.

As described above, according to the transistor integrated circuit device of one embodiment of the present invention, since a wiring metal made into a thin film is used as a resistor, an element destruction caused by thermal runaway can be avoided, and also the integrated area of a circuit can be reduced. In addition, by adopting a cell structure in which one resistor and one capacitor are arranged per a plurality of transistors (2 to 5 are preferable), the integrated area of the circuit can be further reduced, and stabilization of circuit characteristics and an improvement in heat radiation characteristics can be expected as well. Furthermore, according to the method of manufacturing a transistor integrated circuit device of one embodiment of the present invention, the number of manufacturing steps can be reduced relative to the conventional method.

### INDUSTRIAL APPLICABILITY

A transistor integrated circuit device and a method of manufacturing the transistor integrated circuit device of the present invention can be used for a power transistor circuit which handles high frequency signals, and the like, and are especially useful in such cases as requiring the integrated area of a circuit to be reduced while avoiding an element destruction caused by thermal runaway.

1. A transistor integrated circuit device in which circuits are integrated on a semiconductor substrate, the transistor integrated circuit device comprising:
circuits each including:
at least one transistor;
a capacitor having electrodes, to one of which a signal is inputted, and an other of which is connected to a base terminal of the at least one transistor; and
a resistor having terminals, to one of which a direct-current voltage is applied, and an other of which is connected to the base terminal of the at least one transistor, wherein
the resistor is formed from a wiring metal which is made into a thin film.

2. The transistor integrated circuit device according to claim 1, wherein
the resistor is formed integrally with the other electrode of the capacitor, using a same wiring metal as that of the other electrode of the capacitor.

3. The transistor integrated circuit device according to claim 1, wherein
the resistor is formed so as to be multilayered with a wiring for supplying the direct-current voltage.

4. The transistor integrated circuit device according to claim 2, wherein
the resistor is formed so as to be multilayered with a wiring for supplying the direct-current voltage.

5. The transistor integrated circuit device according to claim 1, wherein
the circuit includes one resistor and one capacitor per two to five transistors.

6. The transistor integrated circuit device according to claim 2, wherein
the circuit includes one resistor and one capacitor per two to five transistors.

7. The transistor integrated circuit device according to claim 3, wherein
the circuit includes one resistor and one capacitor per two to five transistors.

8. A method of manufacturing an integrated circuit on a semiconductor substrate, wherein
in a case where the integrated circuit includes at least one transistor; a capacitor having electrodes, to one of which a signal is inputted, and an other of which is connected to a base terminal of the at least one transistor; and a resistor having terminals, to one of which a direct-current voltage is applied, and an other of which is connected to the base terminal of the at least one transistor,
the resistor is formed using a wiring metal which is made into a thin film.

9. The manufacturing method according to claim 8, wherein
the resistor is formed integrally with the other electrode of the capacitor, using a same wiring metal as that of the other electrode of the capacitor and in a same manufacturing step as that for the other electrode of the capacitor.

10. The manufacturing method according to claim 8, wherein
the resistor is formed so as be multilayered with a wiring for supplying the direct-current voltage.

11. The manufacturing method according to claim 9, wherein
the resistor is formed so as to be multilayered with a wiring for supplying the direct-current voltage.
